(19) United States
(12) Patent Application Publication
(10) Pub. No.: US 2002/0145186 A1
(43) Pub. Date: Oct. 10, 2002

(54) Method of forming HSQFN type package

(76) Inventors: Johnson C.H Tzu, Taipei (TW); Hsu Po Chih, Hsinchu (TW); Jerry Y.J. Wu, Taoyuan (TW); Jung Yu Lee, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/829,505

(22) Filed: Apr. 9, 2001

(51) Int. Cl. H01L 23/02

(52) U.S. Cl. 257/678

(57) ABSTRACT

A method of forming a HSQFN (High Stand-off Quad Flat Non-leaded) package comprises providing a leadframe with bonding pads and die pads for receiving a die. Then, the die is attached on the die pad and bonding wires are connected between the bonding pads and the die for electrical connection. Molding process is used to encompass the die by compound from a first surface of the leadframe. Then, backside etching is used to etch the leadframe from a second surface of the leadframe to expose a lower surface of the compound, thereby separating the bonding pads and the die pads. A sigulation is applied to separate each individual package by cutting the leadframe and the compound.

### FIELD OF THE INVENTION

The present invention relates to a semiconductor package, and more specifically, to a method of forming HSQFN (High Stand-off Quad Flat Non-leaded) type package.

### BACKGROUND OF THE INVENTION

Integrated circuits industry and fabrication involve the formation of semiconductor wafers, integrated circuits and chip package. With the advent of Ultra Large Scale Integrated (ULSI) circuits technologies, it has been a trend to scale down the geometry dimension of semiconductor devices and increase the density of semiconductor devices per unit area of silicon wafer. Thus, the sizes of devices, such as memory cells, have gotten smaller and smaller such that the area available for a single device has become very small. Further, the manufacturers of the devices are striving to reduce the sizes while simultaneously increasing their speed. The renewed interest in high density hybrid is driven by the requirement to handle large numbers of IC interconnections, the increasing clock rate of digital systems and the desire to pack greater functionality into smaller spaces. Therefore, the number of a package's leads becomes more and more. An issue is that the package must have the capability to spread the heat generated by the die, efficiently.

For assembling a semiconductor device, a semiconductor chip is properly positioned against the lead frame thus formed, then attached to the insulating film by heat and pressure. Next, the inner leads and their corresponding contact pads are electrically connected by bonding wires using a bonding tool, respectively. Finally, the inner leads and the semiconductor chip are covered by a molding resin to expose the outer leads of the lead frame from the molding resin.

U.S. Pat. No. 6,118,173 to Emoto, entitled “Lead frame and a semiconductor device”. The package includes a chip, inner leads reaches the periphery of the semiconductor chip, and bonding wires for electrically connecting the semiconductor chip and the inner leads. The semiconductor chip is fixed on a die pad portion, and a chip fixing inner lead is integrated with the die pad portion. To simplify the bonding wire connection process and improve the reliability, the chip fixing inner lead has a step portion so that the die pad portion is formed at a lower position than the inner leads. Further, U.S. Pat. No. 6,107,675 disclosed a lead frame structure.

One of the package types is so called QFP (Quad flat package), the QFP is the type used in logic and microprocessor packing that requires up to approximately hundrends pins. The semiconductor memory devices are designed to terminals (leads) for external connection as short as possible in order to make it possible to operate the devices at a higher speed such as the QFN (Quad Flat Non-leaded package) The QFN has a high-speed-oriented package structure in which no leads are provided but electrode pads for soldering are provided to a resin package.

### SUMMARY OF THE INVENTION

The object of the present invention is to provide a package with easier process and improved thermal dissipation.

A method of forming a HSQFN (High Stand-off Quad Flat Non-leaded) package comprising Providing a leadframe with bonding pads and die pads for receiving a die. Then, the die is attached on the die pad and bonding wires are connected between the bonding pads and the die for electrical connection. Molding process is used to encompass the die by compound from a first surface of the leadframe. Then, backside etching is used to the leadframe from a second surface of the leadframe to expose a lower surface of the compound, thereby separating the bonding pads and the die pads. A sigulation is applied to separate each individual package by cutting the leadframe and the compound.

### BRIEF DESCRIPTION OF THE DRAWINGS

FIG. 1 is a cross section view of a step of forming die pad and bonding pad according to the present invention.

FIG. 2 is a cross section view of a step of bonding die on a die pad according to the present invention.

FIG. 3 is a cross section view of a step of bonding wires according to the present invention.

FIG. 4 is a cross section view of a step of molding according to the present invention.

FIG. 5 is a cross section view of a step of backside etching according to the present invention.

FIG. 6 is a cross section view of a step of separating according to the present invention.

### DETAILED DESCRIPTION OF THE PREFERRED EMBODIMENT

The present invention discloses a method for a High Stand-off Quad Flat Non-leaded package technology. A package in accordance with the invention will be described in conjunction with and illustrative embodiment of the invention. Please referring to FIG. 6, the structure of the HSQFN (High Stand-off Quad Flat Non-leaded) includes a leadframe having a die pad 62 and bonding pads 60. The die pad 62 and bonding pads 60 are the portions of the leadframe. The several die pad 62 straightly elongated in parallel relationship to each other from the frame body. The die pad 62 is designed to carry the die 64 adhesived thereon by adhesive material 63. A number of bonding pads 60 formed on the lower surface of the package, and the die 66 is connected to the bonding pads 60 of the lead frame via a plurality of bonding wires 68 for electrical communication. Molding compound 70 encompasses the entire die 66, the bonding wire 68 and the major portion of the lead frame, leaving the terminal of the inner lead exposed out of the body. According to the structure of the present invention, not only the die pad is exposed, but also the lower surface of the bonding pad 60 is exposed. This structure provides excellent 60 thermal dissipation from the packages.

Two stages of etching are used to etch the upper surface (first side) and lower surface (second surface), respectively. The method comprises performing die bonding, wire bonding and molding between two stages of etching. Wherein a first etching of the two stages of etching comprises forming an inward indentation portion of the leadframe from a first side of said leadframe to define die pads and bonding pads. A second etching of the two stages of etching comprises separating the die pads and bonding pads by etching from a second side of the leadframe.

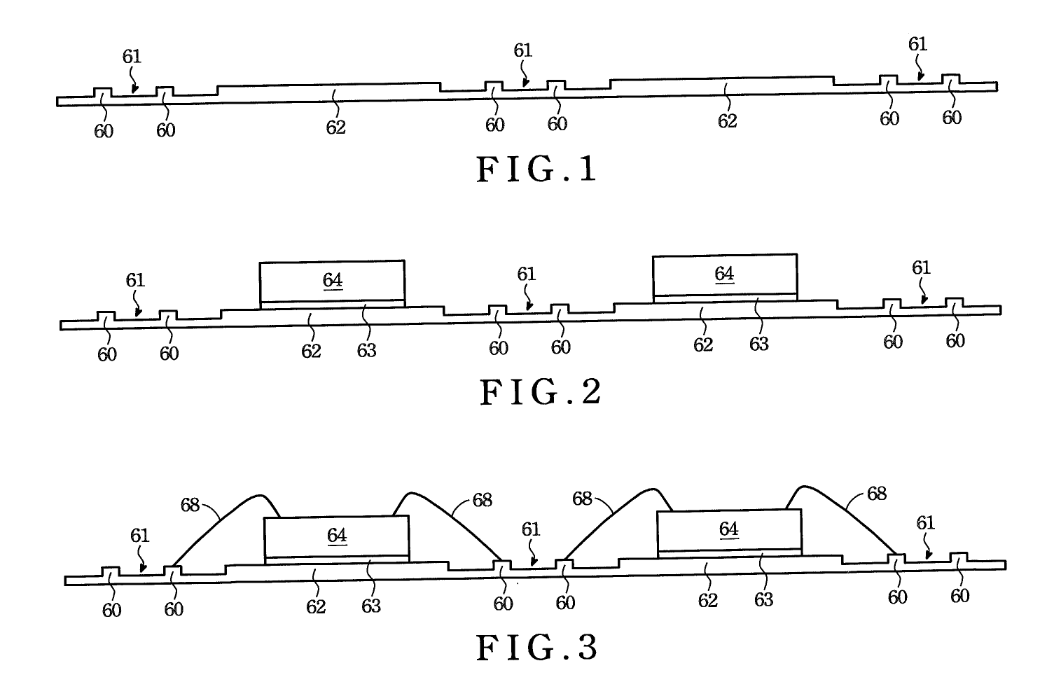

The method for forming the package includes preparing a lead frame having a die pad 62 to receive a die 64, as shown in FIG. 1. This present invention can be achieved by using “stand off” method. In one preferred embodiment, please refer to FIG. 1, the upper surface (the first surface) of the lead frame is etched to form a plurality of inward indentation portions 61. Alternatively, the inward indentation portions 61 may be formed by external force punch.

Next, the die 64 is bonded on the die pad 62 by adhesive material such as silver epoxy 63, as shown in FIG. 2. Subsequently, bonding wires 68 are bonded to connect the die 66 and the connecting pads or bonding pads 60, as illustrated in FIG. 3. Preferably, wire bonding technique is carried out to form the bonding wires for constructing the communication path between the die 66 and the external circuits. The bonding technique is well known in the art, the detailed description is omitted.

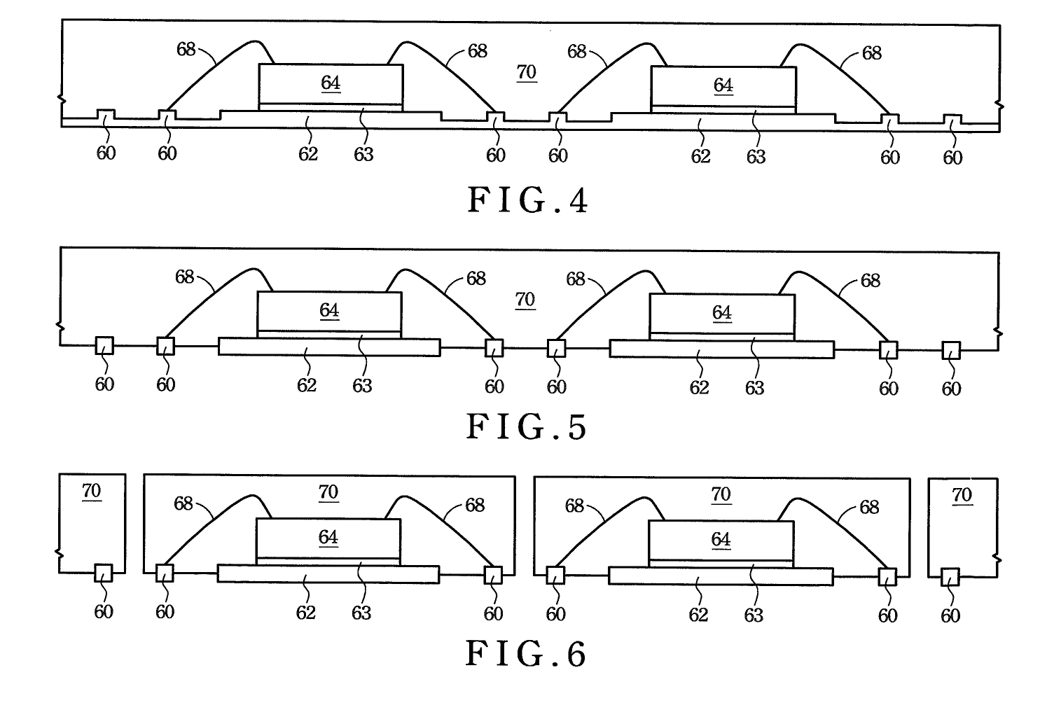

Turning to FIG. 4, the die is encapsulated by mold resin 70. To phrase in another way, molding compound is injected into a mold to form a shielding to protect the die 64 from being damaged by external force. Please turn to FIG. 5, thereafter, PMC (post molding curing) step is performed, this is well known in the art, detailed description is unnecessary. Next, a backside etch is utilized to separate the connection between the die pads 62 and the bonding pads 60. This can be achieved by using lithography and etching process to etch the leadframe from the second surface of the leadframe, thereby exposing the lower surface of the mold resin 70. Other method may be used, as shown in FIG. 5. The etched portions of the leadfram are aligned to the inward indentation portions of the first surface.

Referring to FIG. 6, a sigulation step is performed to separate each individual package. Therefore, the package is cut at specific portions. Optionally, solder ball may be formed on the terminal of the bonding pads.

The benefits of the present invention includes the improvement of heat dissipation characteristic. The die pad which is a portion of the leadfeame is exposed to enhance the thermal dissipation.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A method of forming a HSQFN (High Stand-off Quad Flat Non-leaded) package, comprising:
providing a leadframe with bonding pads and die pads for receiving a die;
attaching a die on said die pad; bonding wires between said bonding pads and said die for electrical connection;
molding said die by compound from a first surface of said leadframe;
backside etching said leadframe from a second surface of said leadframe to expose a lower surface of said compound, thereby separating said bonding pads and said die pads; and
separating each individual package by cutting said leadframe and said compound.

2. The method of claim 1, furthering comprising etching said leadframe to form an inward indentation portions in said leadframe, thereby forming said bonding pads and die pads.

3. The method of claim 1, furthering comprising punching said leadframe to form an inward indentation portions in said leadframe, thereby forming said bonding pads and die pads.

4. The method of claim 1, wherein said die is attached by adhesive material.

5. The method of claim 4, wherein said adhesive material includes epoxy.

6. The method of claim 1, wherein said bonding wires includes gold.

7. A method of forming a HSQFN (High Stand-off Quad Flat Non-leaded) package, comprising:
performing two stages of etching to etch a leadfram from a different surface, wherein further comprising performing die bonding, wire bonding and molding between said two stages of etching;
wherein a first etching of said two stages of etching comprising forming an inward indentation portion of said leadframe from a first side of said leadframe to define die pads and bonding pads; and
wherein a second etching of said two stages of etching comprising separating said die pads and bonding pads by etching from a second side of said leadframe.

8. The method of claim 7, furthering comprising separating each individual package by cutting said leadframe and compound formed by said molding.

9. A HSQFN (High Stand-off Quad Flat Non-leaded) package, comprising:
a leadframe having a die pad and bonding pads, wherein said die pad is designed to carry a die adhesived thereon by adhesive material, wherein said die pad and bonding pads are separated;
a plurality of bonding wires connected between said bonding pads and said die for electrical communication; and
molding compound encompasses said die, said bonding wires and a first surface of said lead frame, leaving the terminal of said bonding pads and the lower surface of said die pad exposed out of said compound for providing excellent thermal dissipation from said packages, wherein said exposed bonding pads is used for communication terminal for said package.

10. The HSQFN package of claim 9, wherein said die is attached by adhesive material.

11. The HSQFN package of claim 10, wherein said adhesive material includes epoxy.

12. The HSQFN package of claim 9, wherein said bonding wires includes gold.
